(19) United States
(12) Patent Application Publication
(10) Pub. No.: US 2013/0015444 A1
(43) Pub. Date: Jan. 17, 2013

(54) EVAPORATION MASK, METHOD OF MANUFACTURING EVAPORATION MASK, ELECTRONIC DEVICE, AND METHOD OF MANUFACTURING ELECTRONIC DEVICE

(71) Applicant: Nobukazu HIRAI, Tokyo (JP)

(72) Inventor: Nobukazu HIRAI, Tokyo (JP)

(73) Assignee: Sony Corporation, Tokyo (JP)

(21) Appl. No.: 13/542,423

(22) Filed: Jul. 5, 2012

(30) Foreign Application Priority Data
Jul. 12, 2011 (JP) 2011-153872

(51) Int. Cl. C23C 16/04; H01L 21/283; B44C 1/22; H01L 51/10

(52) U.S. Cl. 257/57; 438/674; 118/720; 216/12; 257/40; 257/E51.006; 257/E21.159

(57) ABSTRACT

There are provided an evaporation mask with which an evaporated film is allowed to be formed with a fine pattern, a method of manufacturing the same, and a method of manufacturing an electronic device using such an evaporation mask. Further, there is provided an electronic device having a film-formation pattern that is precisely formed with a fine pattern. The evaporation mask including: a substrate including one or a plurality of first opening sections; and a polymer film provided on a first main surface side of the substrate, the polymer film including one or a plurality of second opening sections communicated with the respective first opening sections.

### BACKGROUND

The present disclosure relates to an evaporation mask suitably used in a process of forming a conductive film of an electronic device provided in an electronic circuit or the like and a method of manufacturing the same.

In an electronic device such as a thin film transistor (TFT), a pattern of its electrode section is allowed to be formed by using an evaporation mask (shadow mask). Such an evaporation mask is formed by forming an opening pattern corresponding to the electrode pattern on, for example, a metal plate by wet etching (Japanese Unexamined Patent Application Publication No. 2003-77660). Further, in addition, a method of forming an evaporation mask by what we call an electroforming method has been proposed (Japanese Unexamined Patent Application Publication No. 2006-60054).

### SUMMARY

However, in the foregoing method according to Japanese Unexamined Patent Application Publication No. 2003-77660, a shape and a size of an opening depend on a film thickness of the metal plate (depend on a given aspect ratio of an opening section). The film thickness of the metal plate is equal to or more than several tens of μm. Therefore, in such a method, a minute pattern is less likely to be formed. Meanwhile, in the method using the electroforming method according to Japanese Unexamined Patent Application Publication No. 2006-60054, the mask is formed by electrodepositing a metal material, and therefore unevenness easily occurs in a film thickness of the mask. Further, since an edge of an opening (internal wall section) is easily swollen, a width of the opening is less likely to be controlled.

It is desirable to provide an evaporation mask with which an evaporated film is allowed to be formed with a fine pattern, a method of manufacturing the same, and a method of manufacturing an electronic device using such an evaporation mask. Further, it is desirable to provide an electronic device having a film-formation pattern that is precisely formed with a fine pattern.

According to an embodiment of the present disclosure, there is provided an evaporation mask including a substrate including one or a plurality of first opening sections; and a polymer film provided on a first main surface side of the substrate, the polymer film including one or a plurality of second opening sections communicated with the respective first opening sections.

According to an embodiment of the present disclosure, there is provided a method of manufacturing an evaporation mask, the method including: forming one or a plurality of first opening sections in a substrate; and forming a polymer film including one or a plurality of second opening sections on a first main surface side of the substrate, the one or the plurality of second opening sections being communicated with the one or the plurality of first opening sections.

In the evaporation mask according to the embodiment of the present disclosure and the method of manufacturing an evaporation mask according to the embodiment of the present disclosure, the polymer film is provided on the first main surface side of the substrate having the one or a plurality of first opening sections. The polymer film has the one or a plurality of second opening sections opposed to the respective first opening sections. By passing an evaporation material through the first opening section and the second opening section, an evaporated film is formed with a given pattern. By using the substrate and the polymer film, while the mechanical strength is retained, a more minute and finer opening shape is allowed to be realized in the second opening section than in a case that the evaporation mask is made of only a metal film.

According to an embodiment of the present disclosure, there is provided an electronic device including a conductive film in a selective region on a substrate. In the conductive film, a foot section thereof is tilted with a slope being more moderate as its position is closer to the substrate side.

According to an embodiment of the present disclosure, there is provided a method of manufacturing an electronic device, the method including forming a conductive film by using the evaporation mask. The evaporation mask includes a substrate and a polymer film, the substrate including one or a plurality of first opening sections, and the polymer film being provided on a first main surface side of the substrate and including one or a plurality of second opening sections communicated with the respective first opening sections.

In the evaporation mask according to the embodiment of the present disclosure and the method of manufacturing an evaporation mask according to the embodiment of the present disclosure, the polymer film is provided on the first main surface side of the substrate having the one or a plurality of first opening sections. In the polymer film, the one or a plurality of second opening sections are provided oppositely to the respective first opening sections. Therefore, a minute and precise opening shape is allowed to be realized in the second opening section. Further, an evaporated film is allowed to be formed with a fine pattern. Further, in the electronic device and the method of manufacturing the same according to the embodiments of the present disclosure, by using the foregoing evaporation mask according to the embodiment of the present disclosure in the manufacturing process, a conductive film is allowed to be formed with a fine pattern.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a perspective view illustrating an outline configuration of an evaporation mask according to an embodiment of the present disclosure.

FIG. 2 is a cross-sectional view in the vicinity of an opening of the evaporation mask illustrated in FIG. 1.

FIGS. 3A to 3C are views illustrating a method of manufacturing the evaporation mask illustrated in FIG. 1 in order of steps.

FIGS. 4A to 4C are views illustrating steps following the step in FIG. 3C.

FIGS. 5A and 5B are views illustrating steps following the step in FIG. 4C.

FIG. 6 is a schematic view for explaining an evaporated film formed by using the evaporation mask illustrated in FIG. 1.

FIGS. 7A and 7B are views for explaining a method of manufacturing an evaporation mask according to a first modification.

FIGS. 8A and 8B are a plan view and a cross-sectional view illustrating an example of a TFT formed by using the evaporation mask illustrated in FIG. 1.

FIG. 9 is another cross-sectional view of the TFT illustrated in FIG. 8.

FIGS. 10A and 10B are a plan view and a cross-sectional view illustrating a method of manufacturing the TFT illustrated in FIG. 8 in order of steps.

FIGS. 11A and 11B are views illustrating steps following the step in FIGS. 10A and 10B.

FIGS. 12A and 12B are a plan view and a cross-sectional view illustrating a step following the step in FIGS. 11A and 11B.

FIGS. 13A and 13B are a plan view and a cross-sectional view illustrating a step following the step in FIGS. 12A and 12B.

FIG. 14 is a schematic view illustrating an example of an opening pattern of an evaporation mask used at the time of forming a source and a drain.

FIG. 15 is a schematic view illustrating another example of the opening pattern illustrated in FIG. 14.

FIGS. 16A and 16B are a plan view and a cross-sectional view illustrating a step following the step in FIGS. 13A and 13B.

FIG. 17 is a planar schematic view illustrating an example of an electrode pattern of a TFT.

FIGS. 18A and 18B are planar schematic views illustrating another example of an electrode pattern of a TFT.

FIG. 19 is a schematic view illustrating an opening pattern of an evaporation mask according to a second modification.

FIG. 20 is a schematic view illustrating another example of the opening pattern illustrated in FIG. 19.

### DETAILED DESCRIPTION

An embodiment in the present disclosure will be hereinafter described in detail with reference to the drawings. The description will be given in the following order.

1. Embodiment (example of an evaporation mask having a polymer film on a first main surface side of a substrate)

2. First Modification (another example of a process of forming an opening section)

3. Application Example (example of a TFT in which a source and a drain are formed by using the evaporation mask according to the embodiment)

4. Second Modification (another example of an opening pattern of the evaporation mask used at the time of forming a source and a drain)

### Embodiment

### [Configuration of Evaporation Mask]

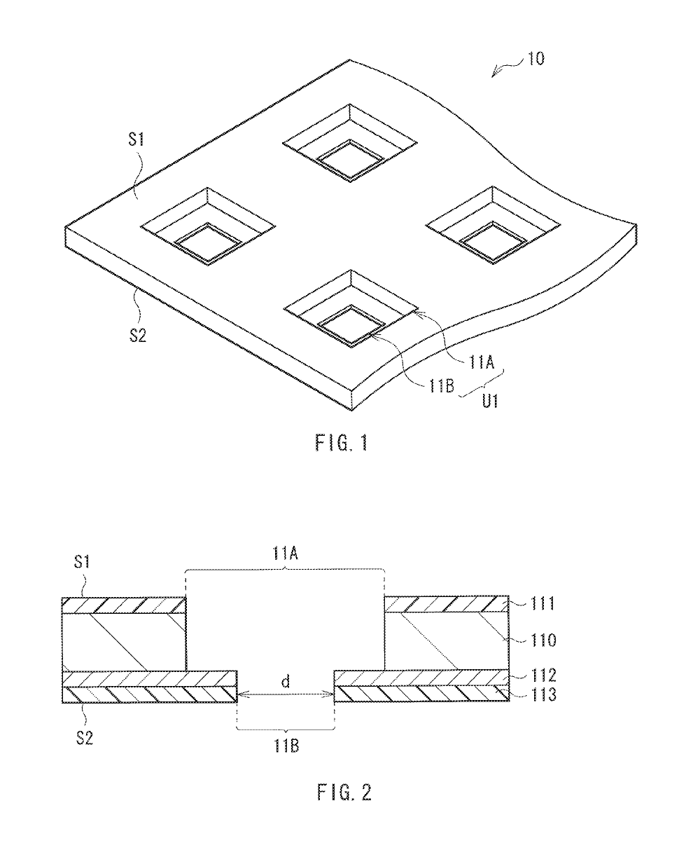

FIG. 1 is a perspective view illustrating an outline configuration of an evaporation mask (evaporation mask 10) according to an embodiment of the present disclosure. The evaporation mask 10 is suitably used in forming a conductive film (in particular, a source electrode and a drain electrode) in an electronic device (for example, an after-mentioned TFT or the like) arranged on, for example, an electronic circuit. In the evaporation mask 10, one or a plurality of openings (openings U1) is provided with a given pattern. In this case, as an example, a description will be given of a case in which a plurality of openings U1 having the same shape are arranged in a state of matrix.

FIG. 2 illustrates a cross-sectional configuration in the vicinity of the opening U1. The evaporation mask 10 is provided with a photoresist film 111 on a surface S1 of a substrate 110 (surface directed to an evaporation source side in evaporation). In the photoresist film 111 and the substrate 110, an opening section 11A (first opening section) penetrating through the photoresist film 111 and the substrate 110 is formed. On the other surface S2 of the substrate 110 (surface to be an evaporated film side in evaporation), a polymer film 112 and a photoresist film 113 are provided in this order. In the photoresist film 113 and the polymer film 112, an opening section 11B (second opening section) penetrating through the photoresist film 113 and the polymer film 112 is formed.

The substrate 110 maintains a shape of the evaporation mask 10 and retains mechanical strength of the evaporation mask 10. For example, the substrate 110 is made of a metal such as SUS (stainless steel), an inorganic material such as glass, or an organic material such as plastic. The substrate 110 is desirably made of a material easily patterned by wet etching.

The thickness of the substrate 110 is, for example, from 20 μm to 1000 μm both inclusive, and is, for example, 50 μm. The lower limit of a scale (shape and size) of an opening shape of the opening section 11A provided in the substrate 110 is subject to the film thickness of the substrate 110 (since the opening section 11A is formed by etching, if the film thickness is large, it is difficult to form the opening section 11A in a minute scale.)

The polymer film 112 is, for example, a single-layer film made of one of polyimide, polyethylene terephthalate (PET), polyether sulfone (PES), polyethylene naphthalate (PEN), polyester, polycarbonate (PC), polyvinyl alcohol (PVA), polyvinyl butyral (PVB), polyacetal , polyarylate (PAR), polyamide (PA), polyamide imide (PAI), polyether imide (PEI), polyphenylene ether (PPE), polyphenylene sulfide (PPS), polyether ketone (PEK), polyphthalamide (PPA), polyether nitrile (PEN), polybenzimidazole (PBI), polycarbodiimide, polysiloxane, polymethacrylic amide, nitrile rubber, acrylic rubber, polyethylene tetrafluoride, an epoxy resin, a phenol resin, a melamine resin, a urea resin, a polymethacrylic methyl resin (PMMA), polybutene polypentene, an ethylene-propylene copolymer, an ethylene-butene-diene copolymer, polybutadiene, polyisoprene, an ethylene-propylene-diene copolymer, butyl rubber, polymethyl pentene (PMP), polystyrene (PS), a styrene-butadiene copolymer, polyethylene (PE), polyvinyl chloride (PVC), polyvinylidene fluoride (PVDF), polyether ether ketone (PEEK), phenol novolak, benzocyclobutene, polyvinyl phenol, polychloropyrene, polyoxymethylene, polysulfone (PSF), and a silicone resin. Alternately, the polymer 112 may be a multilayer film in which two or more of the foregoing materials are layered.

The film thickness of the polymer film 112 is, for example, equal to or less than 20 μm, and is, for example, 5 μm. The film thickness of the polymer film 112 is desirably set to be a value smaller than the thickness of the substrate 110. As in the case of the opening section 11A of the substrate 110 described above, the lower limit of opening scale of the opening section 11B is subject to the film thickness of the polymer film 112. Therefore, in the case where the film thickness of the polymer film 112 is set smaller, the evaporated film is allowed to be formed in a more minute scale precisely.

The opening sections 11A and 11B are communicated with each other, and form the opening U1 of the evaporation mask 10. In this embodiment, in the opening U1, the opening sections 11A and 11B are provided in a fashion of one-to-one correspondence (one opening section 11B is provided for one opening section 11A). However, the opening sections 11A and 11B are not necessarily provided in a fashion of one-to-one correspondence. As described later, a plurality of opening sections 11B may be provided for one opening section 11A. However, in the case where the opening sections 11A and 11B are provided in a fashion of one-to-one correspondence as in this embodiment, intensity of the mask is more easily retained, and shape stability of the opening section 11B is more improved. In this case, for convenience, a description will be given of a case in which the opening Ul is formed of one opening section 11A and one opening section 11B as an example. However, in the opening U1, a plurality of pairs of the opening sections 11A and 11B may be provided according to a film-formation pattern of the evaporated film (hereinafter referred to as evaporation pattern) (described later in detail).

The evaporation mask 10 transmits an evaporation material through the opening U1 from the surface S1 side to the surface S2 side at the time of evaporation. The evaporated film is formed according to an opening shape and a layout (opening pattern) of the opening section 11B. Part or all of the opening shape of the opening section 11B has a minute shape according to the film thickness of the polymer film 112, for example, a shape having an opening width d of, for example, a value equal to or less than 20 μm or desirably a value equal to or less than 10 μm. The opening shape of the opening section 11A may be the same as (including a similar figure) or different from that of the opening section 11B. In this case, for convenience, the respective opening shapes of the opening sections 11A and 11B are rectangles. However, the respective opening shapes of the opening sections 11A and 11B may be other various shapes. Further, the opening section 11A is illustrated one size larger than the opening section 11B. However, sizes thereof are not limited thereto, and for example, in part of the opening U1, the opening section 11A may be formed to be equal to or smaller than the opening section 11B.

### [Method of Manufacturing Evaporation Mask]

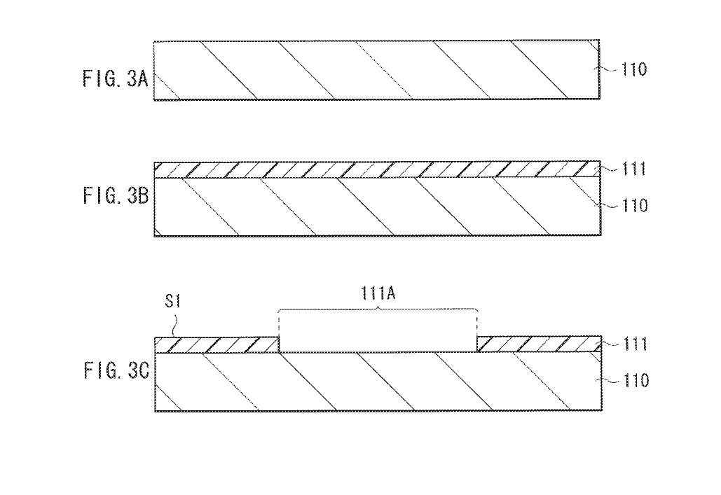

FIGS. 3A to 5B are cross-sectional views for explaining a method of manufacturing the evaporation mask 10. The evaporation mask 10 is allowed to be manufactured, for example, as follows.

First, as illustrated in FIG. 3A, the substrate 110 made of the foregoing material is prepared. In this case, a description will be given of a case in which an SUS substrate is used as the substrate 110. Subsequently, as illustrated in FIG. 3B, one side (surface S1 side) of the substrate 110 is coated with the photoresist film 111. After that, as illustrated in FIG. 3C, an opening 111A corresponding to the opening section 11A is formed in the photoresist film 111 by photolithography method.

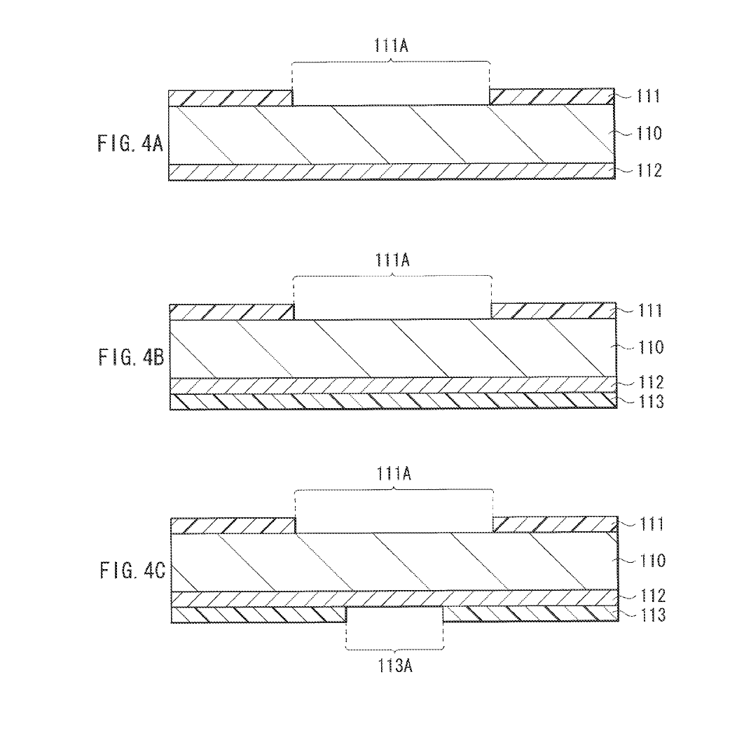

Next, as illustrated in FIG. 4A, the other side (surface S2 side) of the substrate 110 is coated with the polymer film 112 made of the foregoing material. For example, the polymer film 112 having a film thickness of about 5 μm is formed by coating the surface S2 side with polyimide and firing the resultant. In a following step, the opening section 11B is formed in the polymer film 112. The lower limit value of the opening width of the opening section 11B is subject to the film thickness of the polymer film 112. More specifically, the opening section 11B is formed by etching the polymer film 112. At this time, such etching proceeds not only in the thickness direction but also in the width direction. Therefore, according to etching aspect ratio (ratio between a width and a depth capable of being etched), a width naturally generated in etching the film thickness amount at minimum becomes the lower limit of the opening width. Therefore, in forming the polymer film 112, the film thickness is set to a value with which the opening scale demanded in the opening section 11B is allowed to be realized by etching. In other words, as the film thickness of the polymer film 112 is thinner, the opening scale is allowed to be minuter.

Subsequently, as illustrated in FIG. 4B, the polymer film 112 is coated with the photoresist film 113. After that, as illustrated in FIG. 4C, an opening 113A is formed in the photoresist film 113 by photolithography method. A pattern of the opening 113A becomes a pattern of the opening section 11B, that is, an evaporation pattern in the evaporation mask 10.

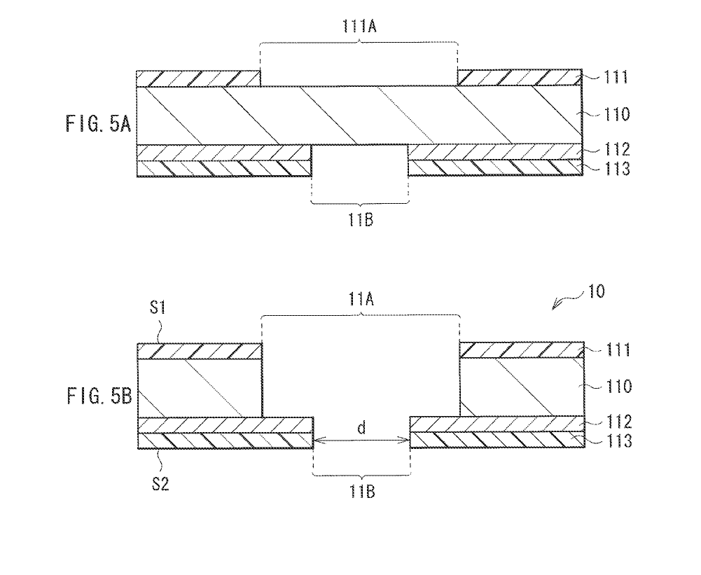

Subsequently, as illustrated in FIG. 5A, the polymer film 112 made of, for example, polyimide is selectively removed by, for example, dry etching, and the opening section 11B is formed in a region corresponding to the opening 113A. After that, as illustrated in FIG. 5B, the substrate 110 made of, for example, SUS is selectively removed by wet etching with the use of, for example, an iron chloride aqueous solution to form the opening section 11A in a region corresponding to the opening 111A. Thereby, the evaporation mask 10 illustrated in FIG. 1 is completed.

It is to be noted that the respective film-formation steps of the photoresist films 111, 113 and the polymer film 112, the etching step of the polymer film 112, and the etching step of the substrate 110 are not limited to the foregoing procedures. For example, the photoresist film 111 may be formed after the polymer film 112 and the photoresist film 113 are formed. Further, the opening section 11B may be formed by etching the polymer film 112 after the opening section 11A is formed by etching the substrate 110.

### [Function and Effect]

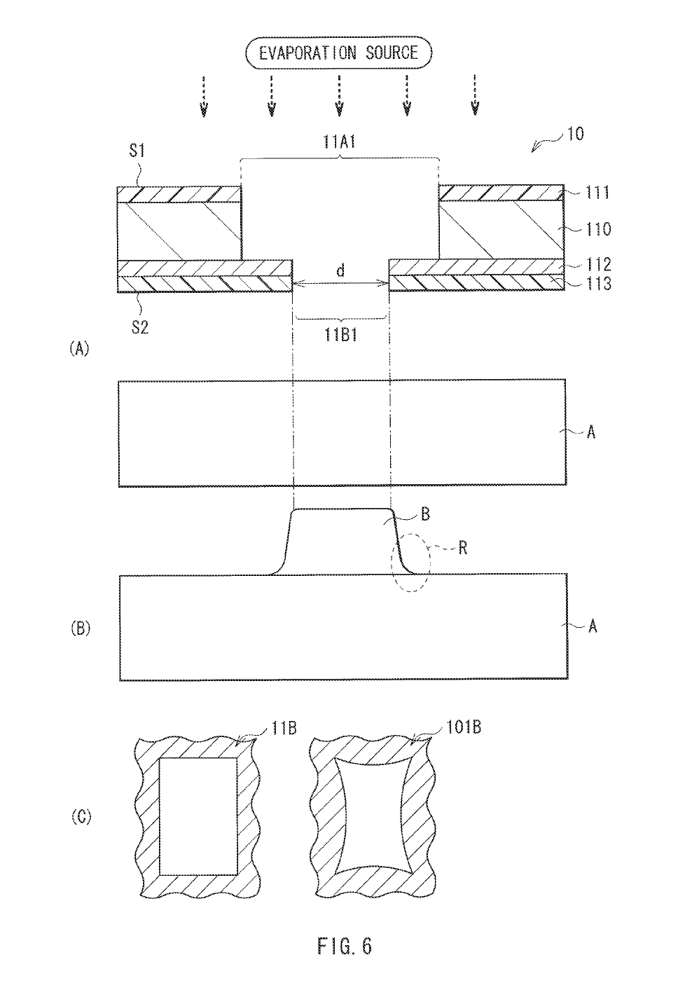

In the evaporation mask 10 according to this embodiment, the polymer film 112 is provided on the surface S2 side of the substrate 110, and the opening sections 11A and 11B communicated with each other (opening U1) are formed respectively in the substrate 110 and the polymer film 112. In evaporation with the use of the evaporation mask 10, as illustrated in (A) of FIG. 6, film formation is made in a state that the surface S1 is directed to the evaporation source side, and the surface S2 is directed to an evaporated substrate A side. Thereby, an evaporation material is sequentially transmitted through the opening sections 11A and 11B, and an evaporated film is formed with a pattern corresponding to the pattern of the opening section 11B. However, in the case where film formation is made by using the evaporation mask 10 according to this embodiment, as illustrated in (B) of FIG. 6, film formation is made so that a slope of a foot section of an evaporated film B is more moderate as its position is closer to the substrate side. This is because, in the case where part of the evaporation material passes through the opening section 11B, such part of the evaporation material is discharged to take a roundabout path to the rear surface side (surface S2 side).

In this embodiment, as described above, the pattern of the opening section 11B of the polymer film 112 corresponds to the evaporation pattern. By combining the polymer film 112 with the substrate 110, the polymer film 112 is allowed to be sufficiently thinned.

More specifically, the opening scale of the opening section 11B is subject to the film thickness. Therefore, to realize miniaturization thereof, the polymer film 112 should be thinned. Even if the polymer film 112 is thinned, mechanical strength (rigidity) of the whole mask is retained by the substrate 110. Therefore, handling thereof is facilitated. If the evaporation mask is made of only a metal film, the film thickness should be equal to or more than several tens of μm in order to retain the strength. Therefore, in the case where the evaporation mask is made of only a metal film, the opening scale is less likely to be miniaturized. Meanwhile, as in this embodiment, in the case where the polymer film is layered on the substrate, while the mechanical strength is retained, the polymer film 112 is allowed to be thinned, and the opening section 11B is allowed to be formed in a minute scale. In addition, by forming the opening sections 11A and 11B by the etching as described above, the cost is allowed to be decreased more and it is easier to address realizing an increased mask area than in a case that a mask is formed by an electroforming method. Further, in the case of using an electroforming method, since a mask is formed by electrodeposition of a metal material, unevenness of the film thickness of the mask easily occurs. Further, as illustrated in (C) of FIG. 6, its edge (internal wall section) of an opening section 101B is easily swollen toward inside, and the opening width is less likely to be controlled. In this embodiment, such a phenomenon does not occur. In this embodiment, the opening section 11B with its edge section in the shape of a substantially straight line is allowed to be obtained, and the mask thickness and the opening width are easily controlled. As described above, while the mechanical strength of the whole mask is retained, the opening section 11B is allowed to be formed with a minute pattern (pattern having an opening width of about several um) precisely. Therefore, in the opening section 11B, a minute and precise opening pattern is allowed to be realized.

As described above, in this embodiment, the substrate 110 and the polymer film 112 are layered, and the opening sections 11A and 11B communicated with each other are provided respectively in the substrate 110 and the polymer film 112. Thereby, while the mechanical strength is retained, the opening section 11B is allowed to be formed minutely and precisely. Therefore, the evaporated film is allowed to be formed with a fine pattern.

In the foregoing embodiment, the photoresist films 111 and 113 remain respectively on the surface S1 side and the surface S2 side of the substrate 110. However, the photoresist films 111 and 113 may be removed after the opening sections 11A and 11B are formed.

### First Modification

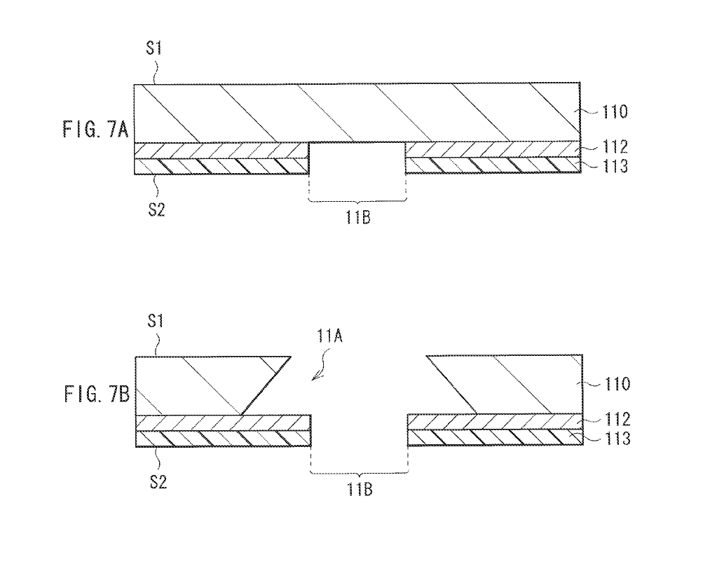

FIGS. 7A and 7B illustrate cross-sectional views for explaining a method of forming an evaporation mask according to a modification (first modification) of the foregoing embodiment. As the evaporation mask 10 according to the foregoing embodiment, the evaporation mask formed by the method according to this modification includes the polymer film 112 and the photoresist film 113 on the surface S2 side of the substrate 110, and has the opening section 11B corresponding to an evaporation pattern in the polymer film 112 and the photoresist film 113. Further, the film thickness of the polymer film 112 is thinner than that of the substrate 110, and for example, is equal to or less than 20 μm. The polymer film 112 is thinned according to the opening scale. It is to be noted that components similar to those of the foregoing embodiment are affixed with the same referential symbols, and descriptions thereof will be omitted.

In this modification, the opening section 11A is formed by the following method different from that of the foregoing embodiment. Specifically, as illustrated in FIG. 7A, after the polymer film 112 is provided and the photoresist film 113 is pattern-formed on the polymer film 112 on the surface S2 side of the substrate 110, the polymer film 112 is etched to form the opening section 11B. Such a process of forming the opening section 11B on the surface S2 side is similar to that of the foregoing embodiment. After that, etching of the substrate 110 is made by using the polymer film 112 and the photoresist film 113 in which the opening section 11B is provided as a mask. Thereby, as illustrated in FIG. 7B, the opening section 11A is formed in the substrate 110. In the evaporation mask formed as above, a cross-sectional shape of the opening section 11A has a wider width in a first main surface side (polymer film 112 side) than in a second main surface side (surface S1 side). The width on the surface S1 side of the opening section 11A is formed larger than that of the opening section 11B. In other words, in this modification, the width of a section opposed to the polymer film 112 of the opening section 11A is the largest, the width on the surface S1 side of the opening section 11A is the second-largest, and the width of the opening section 11B of the polymer film 112 is the smallest. Further, at the time of usage, the evaporation mask according to this modification is also arranged so that the opening section 11B on the polymer film 112 side is directed to the evaporated side as in the foregoing embodiment.

As in this modification, the opening section 11A of the substrate 110 may be formed by etching with the use of the opening section 11B of the polymer film 112. In this case, effects equal to those of the foregoing embodiment are obtainable as well.

### Application Example

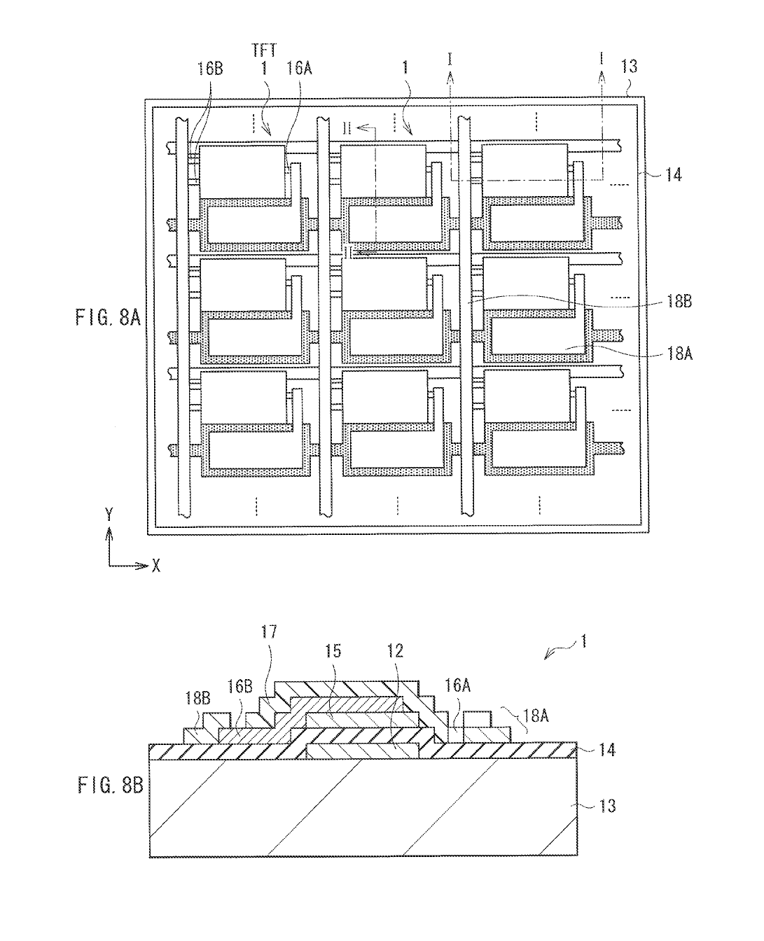

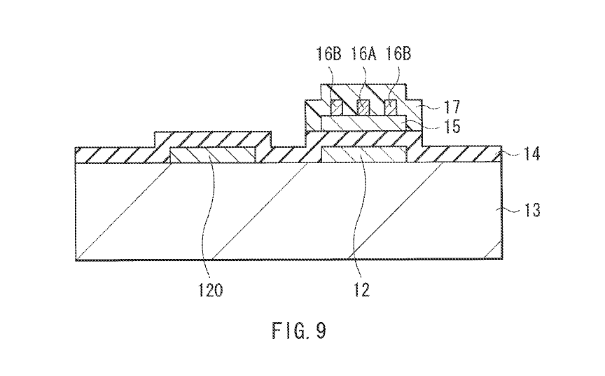

FIGS. 8A, 8B, and 9 illustrate an example of an electronic device (TFT 1) formed by using the foregoing evaporation mask 10. FIG. 8A is a view of a plurality of TFTs 1 provided in a state of matrix on a substrate 13, which is seen from the upper surface side (XY plan view). FIG. 8B is a cross-sectional view taken along a line I-I of FIG. 8A. FIG. 9 is a cross-sectional view taken along a line II-II in FIG. 8A. The TFT 1 is a drive device used in a display unit such as an active matrix organic EL display unit, a liquid crystal display unit, and an electronic paper. The TFT 1 is, for example, an organic thin film transistor using an organic semiconductor, and has what we call a bottom-gate top-contact structure. In the TFT 1, a gate electrode 12 and a semiconductor layer 15 are oppositely arranged with a gate insulating film 14 in between. The TFT 1 has a source electrode 16A and a drain electrode 16B that are electrically connected to the semiconductor layer 15. The source electrode 16A and the drain electrode 16B correspond to a specific example of “conductive film” of the present disclosure.

The TFT 1 includes the gate electrode 12 in a selective region on the substrate 13. The TFT 1 has the gate insulating film 14 over the whole surface of the substrate 13 to cover the gate electrode 12. In a selective region on the gate insulating film 14 (region opposed to the gate electrode 12), the semiconductor layer 15 is formed. On the semiconductor layer 15, the source electrode 16A and the drain electrode 16B are provided with a given pattern. Though details will be described later, the source electrode 16A and the drain electrode 16B are formed with a minute pattern. For example, the source electrode 16A and the drain electrode 16B are formed by evaporation with the use of the foregoing evaporation mask 10. A protective film 17 is formed to cover part of the source electrode 16A and the drain electrode 16B and the semiconductor layer 15. The source electrode 16A and the drain electrode 16B are respectively led out from the upper surface of the semiconductor layer 15 to a given region on the gate insulating film 14 (region where the source electrode 16A and the drain electrode 16B are exposed from the protective film 17). The source electrode 16A and the drain electrode 16B are respectively and electrically connected to wiring layers 18A and 18B on the gate insulating film 14.

The substrate 13 is formed by using, for example, a plastic sheet made of polyimide, polyethylene terephthalate, polyether sulfone, polyethylene naphthalate, polycarbonate, a liquid crystal polymer, or the like, or a metal sheet made of stainless steel, aluminum (Al), copper (Cu), or the like with its surface treated with insulation process.

The gate electrode 12 controls a carrier density in the semiconductor layer 15 by a gate voltage (Vg) applied to the TFT 1, and has a function as a wiring supplying an electric potential. The gate electrode 12 is made of, for example, one simple substance of aluminum, platinum (Pt), gold (Au), palladium (Pd), chromium (Cr), nickel (Ni), molybdenum (Mo), niobium (Nb), neodymium (Nd), rubidium (Rb), rhodium (Rh), aluminum (Al), silver (Ag), tantalum (Ta), tungsten (W), titanium (Ti), copper, indium (In), and tin (Sn); an alloy containing one or more thereof or a laminated film formed of two or more thereof.

The gate insulating film 14 is, for example, a single layer film formed of one of polyvinyl phenol, diarylphthalate, polyimide, polymethacrylic acid methyl, polyvinyl alcohol, polyester, polyethylene, polycarbonate, polyamide, polyamideimide, polyether imide, polysiloxane, polymethacrylamide, polyurethane, polybutadiene, polystyrene, polyvinyl chloride, nitrile rubber, acryl rubber, butyl rubber, an epoxy resin, a phenol resin, a melamine resin, a urea resin, a novolac resin, a fluorine-based resin, and the like, or a laminated film formed of two or more thereof Part of the foregoing material may be pattern-formed by a printing technology such as ink-jet printing, screen printing, off-set printing, and gravure printing.

The semiconductor layer 15 is intended to form a channel by application of a gate voltage. The semiconductor layer 15 is formed of, for example, a peri-Xanthenoxanthene (PXX) derivative. In addition, examples of the material of the semiconductor layer 15 include polypyrrole and a polypyrrole substitution product; polythiophene and a polythiophene substitution product; isothianaphthenes such as polyisothianaphthene; thienylenevinylenes such as polythienylenevinylene; poly(p-phenylenevinylene)s such as poly(p-phenylenevinylene); polyaniline and a polyaniline substitution product; polyacetylenes; polydiacetylenes; poly azulenes; polypyrenes; polycarbazoles; polyselenophenes; polyflans; poly(p-phenylene)s; polyindoles; polypyridazines; a polymer and a polycyclic condensed body such as polyvinyl carbazole, polyphenylene sulfide, and polyvinylenesulfide; oligomers having the same repetition unit as that of a polymer in the foregoing materials; acens such as naphthacene, pentacene, hexacene, heptacene, dibenzopentacene, tetrabenzopentacene, pyrene, divenzopyrene, chrisene, perylene, coronene, terrylene, ovalene, quaterrylene, and circumanthracene; a derivative obtained by substituting part of carbons in acens by an atom such as N, S, and O or a functional group such as a carbonyl group (triphenodioxazine, triphenodithiazine, hexacene-6,15-quinone, or the like); metal phthalocyanines; tetrathiafulvalene and a tetrathiafulvalene derivative; tetrathiapentalene and a tetrathiapentalene derivative; naphthalene tetracarboxylic diimides such as naphthalene 1,4,5,8-tetracarboxylic diimide, N,N′-bis(4-trifluoromethyl benzil)naphthalene 1,4,5,8-tetracarboxylic diimide, N,N′-bis(1H, 1H-perfluoroctyl), N,N′-bis(1H, 1H-perfluorobutyl), an N,N′-dioctyl naphthalene 1,4,5,8-tetracarboxylic diimide derivative, and naphthalene 2,3,6,7 tetracarboxylic diimide; condensed ring tetracarboxylic diimides such as anthracene tetracarboxylic diimides such as anthracene 2,3,6,7-tetracarboxylic diimide; fullerenes such as C60, C70, C76, C78, and C84; a carbon nanotube such as SWNT; a derivative of one of dyes such as graphene, merocyanine dyes, and hemicyanine dyes; and a mixture of two or more materials thereof.

The source electrode 16A and the drain electrode 16B are arranged being electrically separated in a region corresponding to a channel 13C of the semiconductor layer 15. The source electrode 16A and the drain electrode 16B are respectively made of, for example, gold. In addition, as a component material of the source electrode 16A and the drain electrode 16B, for example, a metal or a transparent conductive film equivalent to those listed in the foregoing gate electrode 12. Though details will be described later, one or a plurality of the source electrodes 16A and one or a plurality of the drain electrodes 16B respectively extend in one direction (X direction), having a width from 1 μm to 20 μm both inclusive and a minute scale. Respective foot sections R of the source electrode 16A and the drain electrode 16B are formed by using the evaporation mask 10. Therefore, as described above, the foot sections R have a shape in which its slope is more moderate as its position is closer to the substrate 13 side.

The protective film 17 is intended to protect the semiconductor layer 15, and is made of, for example, a fluorine-based resin. Alternately, the protective film 17 may be made of polyparaxylene or the like.

The wiring layers 18A and 18B are made of, for example, copper. In this case, the wiring layer 18A is arranged for every TFT 1, and each thereof is electrically connected to the source electrode 16A. For example, the wiring layer 18B extends in the Y direction, is provided as a wiring layer common to the drain electrodes 16B of the plurality of TFTs 1 being lined in the row direction, and is electrically connected to the respective drain electrodes 16B. It is to be noted that the foregoing shape and the foregoing layout of the wiring layers 18A and 18B are only an example, and other various patterns may be adopted.

### [Method of Forming TFT 1]

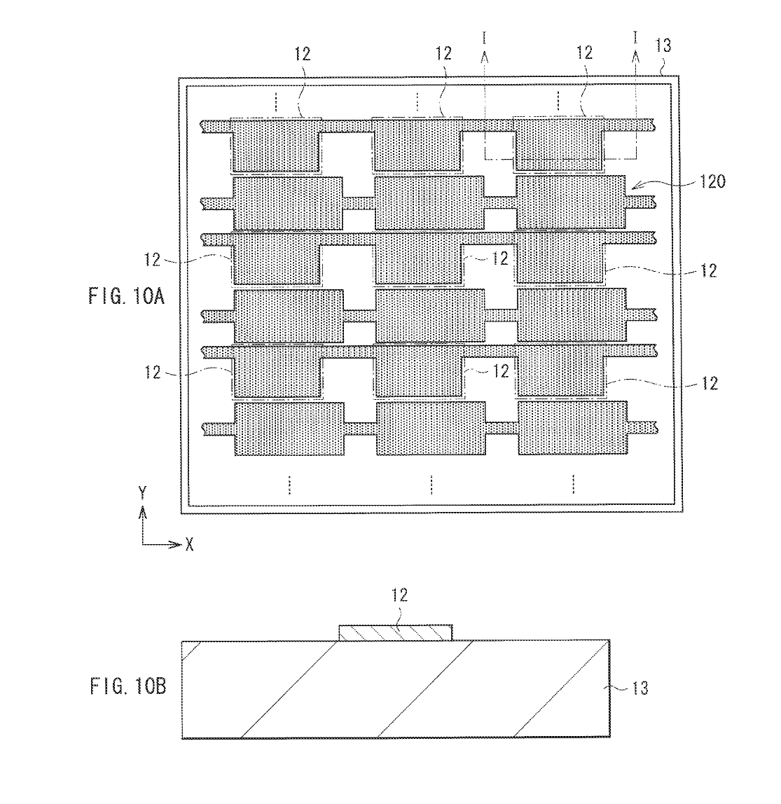

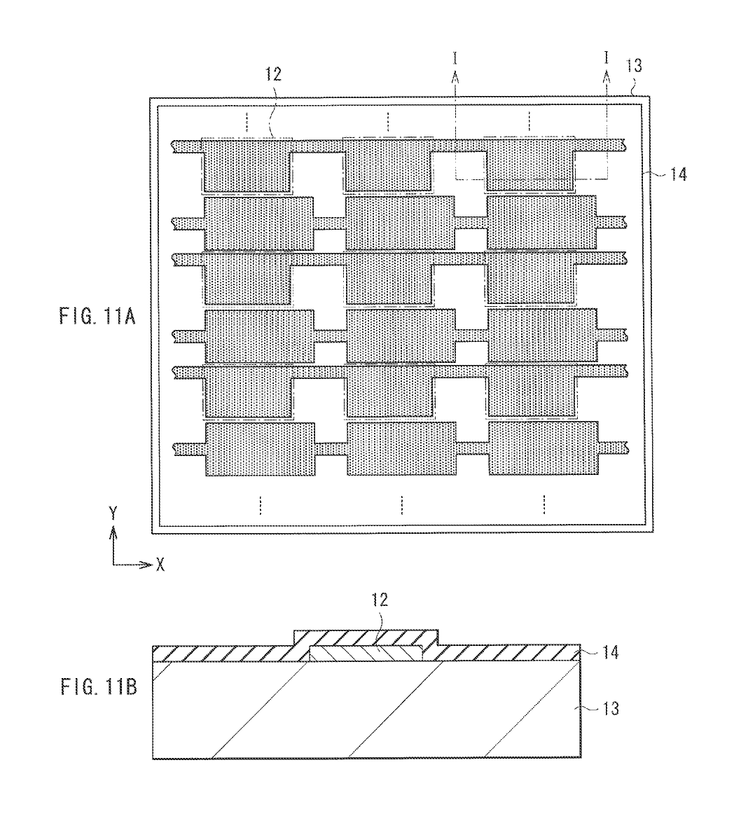

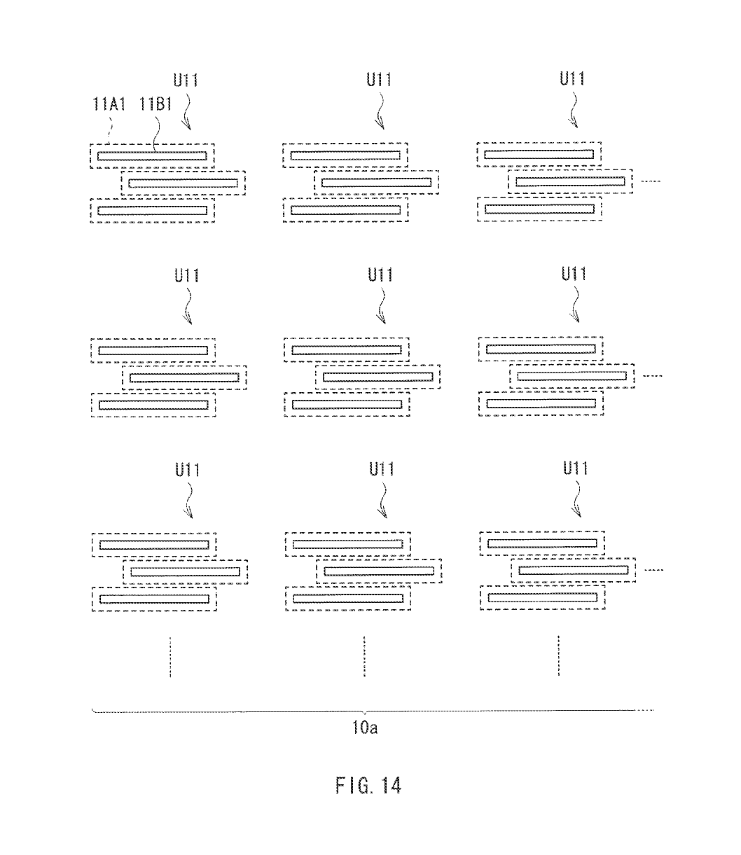

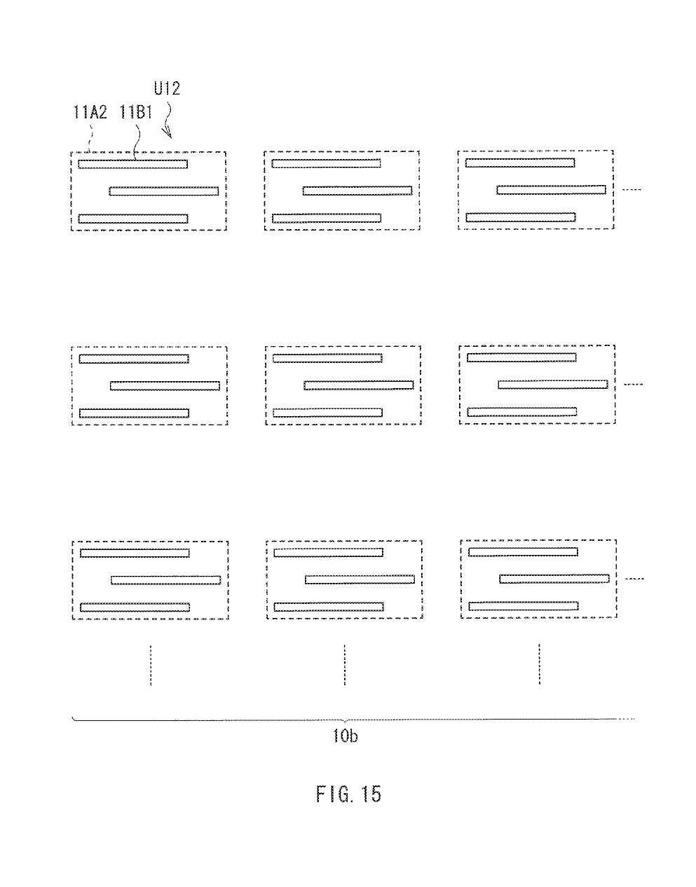

FIGS. 10A to 16B are views for explaining a method of manufacturing the TFT 1. FIGS. 14 and 15 schematically illustrate examples of opening patterns of an evaporation mask used at the time of forming the source electrode 16A and the drain electrode 16B. The TFT 1 is allowed to be manufactured, for example, as follows.

First, as illustrated in FIGS. 10A and 10B, the gate electrode 12 is formed in a selective region on the substrate 13. Specifically, first, the foregoing gate electrode material such as aluminum is deposited over the whole surface of the substrate 13 by, for example, a sputtering method. After that, patterning is made in a given shape by etching using, for example, a photolithography method. At this time, for example, as illustrated in the figure, other electrode layer 120 (an electrode for contact or an electrode for forming a capacity) is preferably patterned in block together with the gate electrode 12. Accordingly, the gate electrode 12 is formed on the substrate 13. It is to be noted that the foregoing shape and the foregoing layout of the gate electrode 12 and the electrode layer 120 are only an example, and the shape and the layout thereof are not limited thereto.

Subsequently, as illustrated in FIGS. 11A and 11B, the gate insulating film 14 is formed over the whole surface of the substrate 13. Specifically, the substrate 13 is coated with the foregoing material of the gate insulating film such as a polyvinyl phenol aqueous solution by, for example, a spin coat method, the resultant is dried to form the gate insulating film 14. Alternately, at this time, according to a material to be used, other film-formation method, for example, a printing method such as ink-jet printing, screen printing, off-set printing, and gravure printing may be used. In FIG. 11A, for convenience, only an edge section of the gate insulating film 14 is indicated, and the gate electrode 12 provided in the lower layer is indicated by full lines.

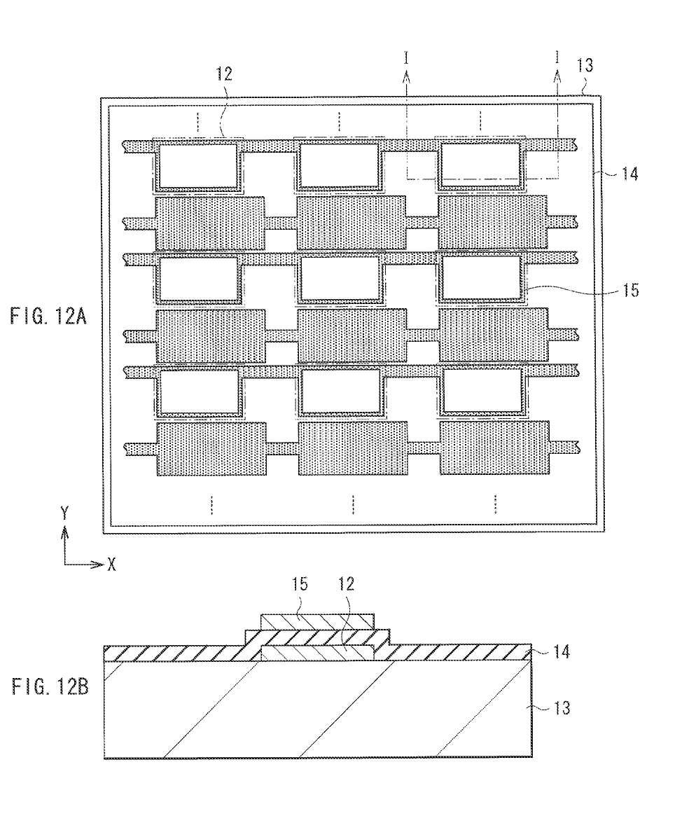

Next, as illustrated in FIGS. 12A and 12B, in a selective region on the gate insulating film 14 (region opposed to the gate electrode 12), the semiconductor layer 15 is formed. Specifically, the gate insulating film 14 is coated with a peri-Xanthenoxanthene compound solution, the resultant is heated to form the semiconductor layer 15.

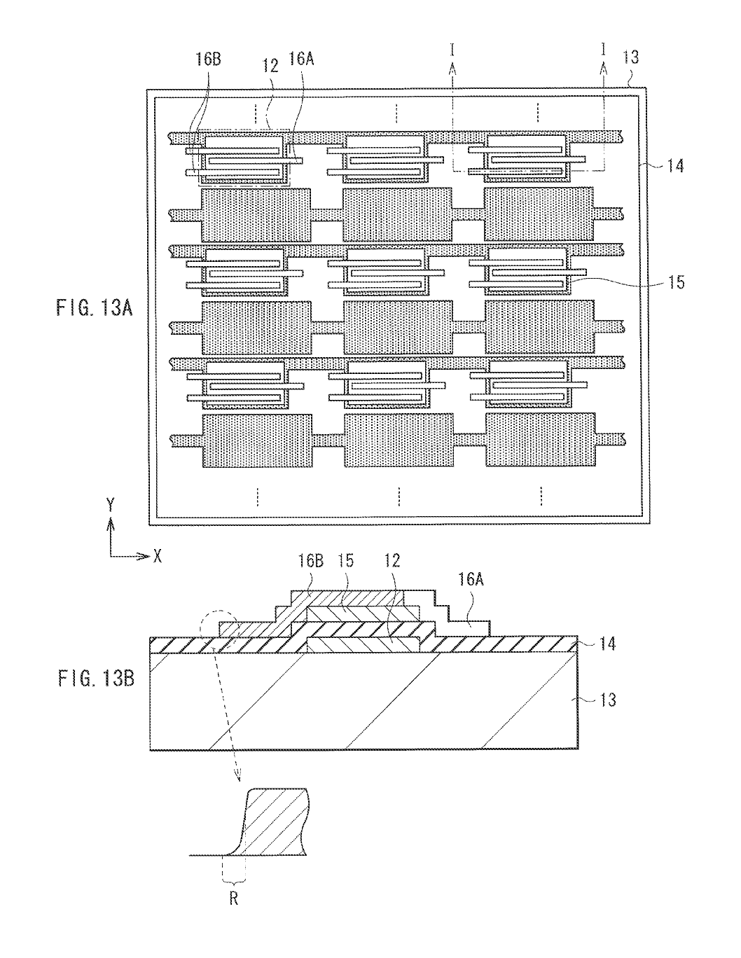

After that, as illustrated in FIGS. 13A and 13B, the source electrode 16A and the drain electrode 16B are formed on the semiconductor layer 15. Specifically, by using the evaporation mask 10 according to the foregoing embodiment, the foregoing electrode material such as gold is evaporated with a given pattern. A description will be hereinafter given of an example (electrode pattern example) of shapes (XY planar shapes) and layouts of the source electrode 16A and the drain electrode 16B, and examples (opening pattern examples) of shapes and layouts of the opening in the evaporation mask 10 capable of forming the source electrode 16A and the drain electrode 16B.

### [Example of Electrode Pattern]

For example, as illustrated in FIG. 13A, the source electrode 16A and the drain electrode 16B respectively have a linear shape with the foregoing minute width extending in one direction (X direction). One or a plurality of the source electrodes 16A and one or a plurality of the drain electrodes 16B are respectively and alternately arranged in a direction substantially perpendicular to the extending direction thereof. Specifically, arrangement is made so that one source electrode 16A is sandwiched between two drain electrodes 16B on the semiconductor layer 15. The source electrode 16A and the drain electrode 16B are led out from the upper surface of the semiconductor layer 15 to a given region on the gate insulating film 14 in each direction opposite to each other. As described above, respective foot sections R of the source electrode 16A and the drain electrode 16B are in the shape in which their slopes are more moderate as their positions are closer to the substrate 13 side by being formed with the use of the evaporation mask 10.

### [Examples of Opening Pattern]

FIG. 14 schematically illustrates an opening pattern (opening pattern 10a) of the evaporation mask 10 for forming the foregoing electrode pattern. In the opening pattern 10a, a plurality of openings U11 are arranged, for example, in a state of matrix. Each of the openings U11 is formed of an opening section 11A1 (dashed line section) and an opening section 11B1 (solid line section). The opening U11 corresponds to a specific example of the opening U1 in the foregoing evaporation mask 10, the opening section 11A1 corresponds to a specific example of the opening section 11A, and the opening section 11B1 corresponds to a specific example of the opening section 11B. In this example, the opening section 11B1 is provided according to the respective shapes and the respective layouts of the source electrode 16A and the drain electrode 16B described above. The opening sections 11B1 and 11A1 are oppositely provided in a fashion of one-to-one correspondence.

Alternately, an opening pattern (opening pattern 10b) as illustrated in FIG. 15 may be used. In the opening pattern 10b, as in the foregoing opening pattern 10a, a plurality of openings U12 are arranged in a state of matrix. Each of the openings U12 is formed of an opening section 11A2 (dashed line section) and an opening section 11B1 (solid line section). The opening U12 corresponds to a specific example of the opening U1 in the foregoing evaporation mask 10, the opening section 11A2 corresponds to a specific example of the opening section 11A, and the opening section 11B1 corresponds to a specific example of the opening section 11B. In this example, again, the opening section 11B1 is provided according to the respective shapes and the respective layouts of the source electrode 16A and the drain electrode 16B described above. The opening section 11B1 is opposed to the opening section 11A2. However, in the opening pattern 10b, one opening section 11A2 is provided being opposed to a plurality of (in this case, three) opening sections 11B1. Such an opening pattern 10b may be used. However, as described above, in terms of shape stability, the foregoing opening pattern 10a is desirably used.

By using the evaporation mask 10 having the foregoing opening pattern, the source electrode 16A and the drain electrode 16B are allowed to be formed minutely and precisely. Further, since no etching process exists, the electrodes are allowed to be formed without damaging the semiconductor layer 15.

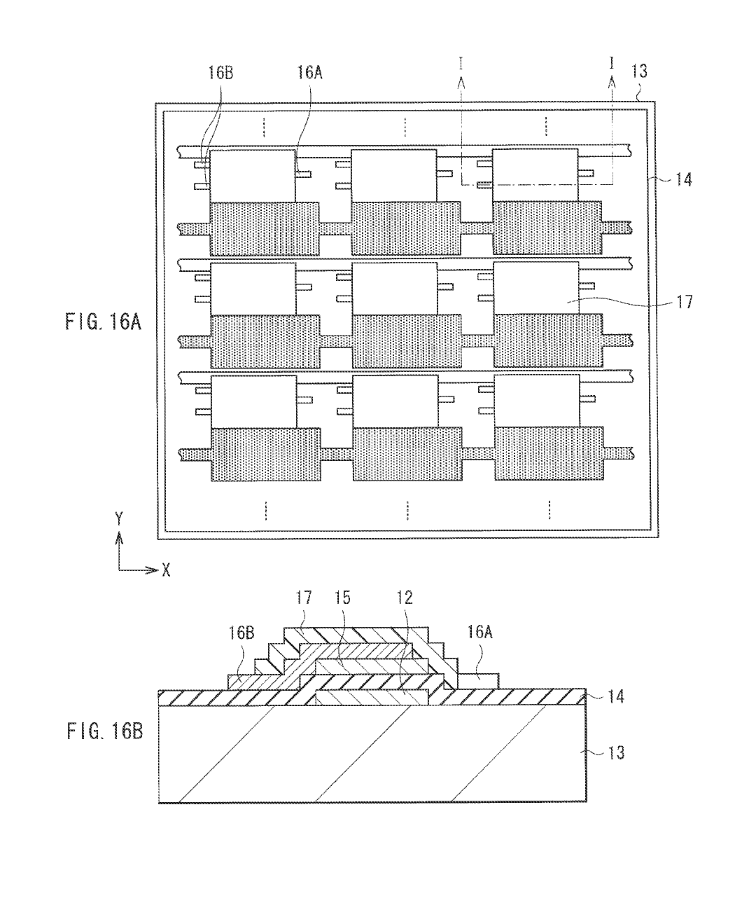

Next, as illustrated in FIGS. 16A and 16B, the protective film 17 is formed to cover the semiconductor layer 15. Specifically, the semiconductor layer 15 is coated with the protective film 17 made of, for example, a fluorine-based resin, and patterning is made by, for example, a photolithography method so that part of the source electrode 16A and the drain electrode 16B (section provided adjacently to the gate insulating film 14) is exposed. It is to be noted that the semiconductor layer 15 is desirably coated with a material dissolved in an orthogonal solvent with respect to the semiconductor layer 15 as a material of the protective film. In the case where polyparaxylene is used as a material of the protective film, the protective film 17 is allowed to be formed by, for example, a CVD (chemical vapor deposition) method.

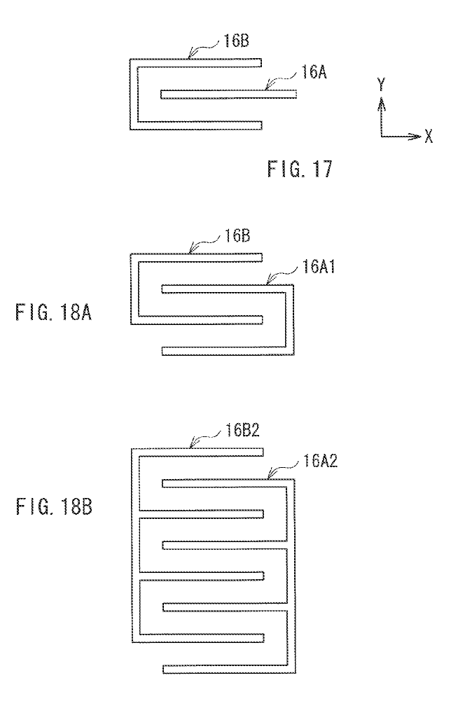

Finally, the wiring layers 18A and 18B are formed. Specifically, after the foregoing material of the wiring layer such as copper is deposited by, for example, a sputtering method, patterning is made by wet etching using, for example, a photolithography method, and thereby the wiring layers 18A and 18B are formed in block. At this time, patterning is made so that, for example, the wiring layer 18A is electrically connected to the exposed section of the source electrode 16A, and the wiring layer 18B is electrically connected to the exposed section of the drain electrode 16B. As schematically illustrated in FIG. 17, by connecting the wiring layers 18A and 18B to the source electrode 16A and the drain electrode 16B respectively, in each TFT 1, an electrode pattern in which part of the source electrode 16A extending in the X direction is sandwiched between sections of the drain electrode 16B in the shape of U in the XY planer surface is formed. Accordingly, the TFT 1 illustrated in FIGS. 8A and 8B is completed.

As described above, by using the evaporation mask 10 according to the foregoing embodiment, for example, the source electrode 16A and the drain electrode 16B are allowed to be formed with a fine pattern. Thereby, in an electronic device such as a TFT, a conductive film such as an electrode is allowed to be formed with a complicated and minute pattern, and high performance of the device is allowed to be realized.

In the foregoing embodiment, the description has been given of the electrode pattern in which one source electrode 16A and two drain electrodes 16B are alternately provided and the opening patterns of the evaporation mask 10 as an example. However, the number of the source electrodes 16A and the drain electrodes 16B and layouts thereof are not limited thereto.

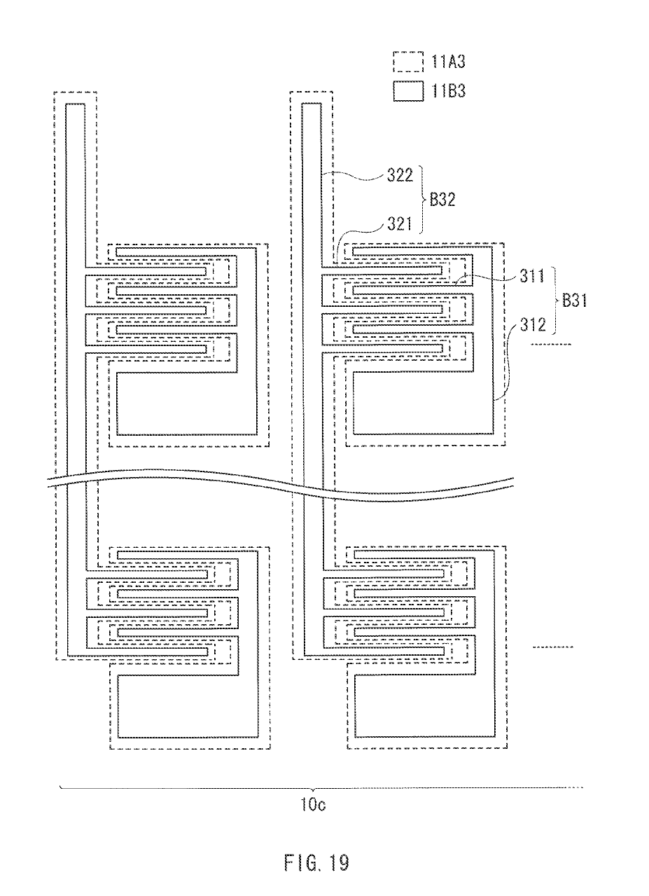

For example, the number of openings with an opening pattern may be increased, and two or more source electrodes 16A and two or more drain electrodes 16B may be respectively and alternately provided. In the case where two source electrodes 16A and two drain electrodes 16B are alternately arranged, by finally connecting them to the wiring layers 18A and 18B, a source electrode 16A1 in the shape of U and the drain electrode 16B in the shape of U as illustrated in FIG. 18A are allowed to be formed. Further, in the case where three or more source electrodes 16A and three or more drain electrodes 16B are respectively and alternately arranged, a source electrode 16A2 in the shape of a comb and a drain electrode 16B2 in the shape of a comb as illustrated in FIG. 18B are allowed to be formed. It is to be noted that in the case of the comb-like shape, the number of teeth of the source electrodes 16A and the drain electrodes 16B is not particularly limited. A description will be hereinafter given of another example of a method of forming an electrode pattern taking an example of a case in which such an electrode pattern in the shape of a comb is formed.

### Second Modification

FIG. 19 is a schematic view of an opening pattern (opening pattern 10c) of the evaporation mask 10 in the foregoing embodiment. As in the foregoing opening patterns 10a and 10b, the opening pattern 10c is used in forming a source electrode and a drain electrode respectively in a region in which a plurality of TFTs arranged in a state of matrix are formed. Further, the opening pattern 10c has an opening section 11A3 as a specific example of the opening section 11A and an opening section 11B3 as a specific example of the opening section 11B. As in the foregoing opening pattern 10a, the opening sections 11A3 and 11B3 are provided in a fashion of one-to-one correspondence. However, in this modification, an electrode pattern of the source electrode and the drain electrode, and wiring layers (corresponding to the foregoing wiring layers 18A and 18B) electrically connected to the source electrode and the drain electrode respectively is included in one mask (one opening pattern).

Specifically, in the opening pattern 10c, as the opening section 11B3, a unit opening B31 having a comb-like shape in part or all thereof and a unit opening B32 similarly having a comb-like shape are arranged so that respective tooth sections are engaged. For example, in the unit opening B31, an electrode opening 311 (for forming the source electrode) corresponding to a source electrode section (tooth section) and a wiring opening 312 corresponding to a wiring section connected thereto are integrally formed (being connected with each other). The unit opening B31 is, for example, provided for every TFT. For example, in the unit opening B32, an electrode opening 321 corresponding to a drain electrode section (tooth section) and a wiring opening 322 corresponding to a wiring section connected thereto are integrally formed. The unit openings B32 are connected with each other in the column direction (the wiring opening 322 is commonly used in the unit openings B32 arranged in the column direction). The opening section 11A3 is in the shape similar to the minute shape of the opening section 11B3, and is provided one size larger than the opening section 11B3.

By using the evaporation mask 10 having the foregoing opening pattern 10c, in the foregoing manufacturing process of the TFT 1, the source electrode and the drain electrode each having a comb-like shape and the wiring layers connected to the respective electrodes are formed in block in the same step. Therefore, these respective layers are allowed to be formed with a fine pattern, the number of steps is allowed to be decreased, and the manufacturing process is allowed to be simplified.

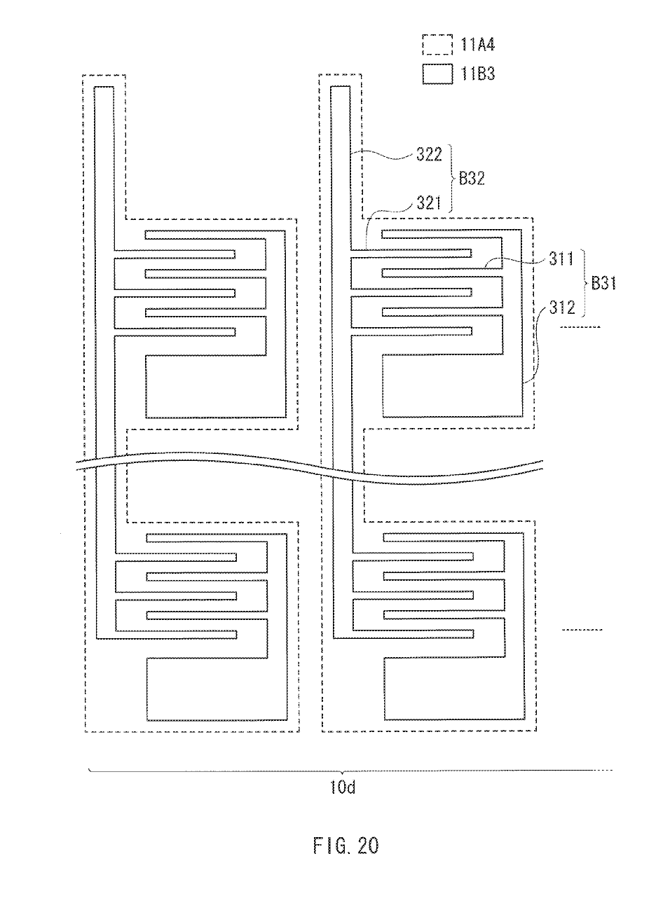

In this modification, the description has been given of the case in which the opening sections 11A3 and 11B3 are provided in a fashion of one-to-one correspondence as an example. However, in this modification, again, a plurality of opening sections 11B3 may be provided oppositely to one opening section 11A3. For example, as an opening pattern 10d illustrated in FIG. 20, a plurality of unit openings B31 and B32 arranged in the column direction may be provided oppositely to one opening section 11A4 (specific example of the opening section 11A). However, in terms of shape stability, the opening pattern 10c illustrated in FIG. 19 is desirably used.

The present disclosure has been described with reference to the embodiment, the application example, and the modifications. However, the present disclosure is not limited to the foregoing embodiment and the like, and various modifications may be made. For example, an opening pattern of the evaporation mask and an evaporated film pattern formed by using the same are not limited to the foregoing opening pattern and the foregoing evaporated film pattern, and various shapes and various layouts may be adopted. In particular, by using the evaporation mask according to the embodiment of the present disclosure, each layer is allowed to be precisely formed even in the case of a pattern having an extending linear section with a minute width of about from several μm to 20 μm both inclusive, in the case of a pattern in which a plurality of such linear sections are arranged at minute intervals, or in the case of a pattern in which such a linear section is combined with other shape. Further, a shape of such a miniaturized section is not limited to the linear shape (straight line shape) extending in one direction, and may be a curved shape. Further, in addition to the linear shape, for example, a polygonal shape having a length of one side in the range from several μm to 20 μm, a circular shape having a diameter in such a range, an oval shape having a diameter in such a range, or the like may be adopted.

Further, in the foregoing embodiment and the like, the organic TFT having a bottom-gate top-contact structure is taken as an example of an electronic device according to the embodiment of the present disclosure. However, an electronic device is not limited to the TFT, and any active device demanding pattern formation of a conductive film is applicable. The structure of the TFT is not limited to the foregoing structure, and may be a structure using semiconductor other than the organic semiconductor such as inorganic semiconductor and oxide semiconductor. Further, a bottom-gate bottom-contact structure or a top-gate structure (both bottom contact type and top contact type are applicable) is applicable.

Further, in the foregoing embodiment and the like, the source electrode and the drain electrode of the TFT are taken as an example of a conductive film in the electronic device according to the embodiment of the present disclosure. However, as a conductive film, other electrode and other wiring in the TFT may be formed by the evaporation mask according to the embodiment of the present disclosure. However, the evaporation mask according to the embodiment of the present disclosure is suitable for forming a conductive film having a minute scale.

It is possible to achieve at least the following configurations from the above-described exemplary embodiment and the modifications of the disclosure.

(1) An evaporation mask including:
a substrate including one or a plurality of first opening sections; and
a polymer film provided on a first main surface side of the substrate, the polymer film including one or a plurality of second opening sections communicated with the respective first opening sections.

(2) The evaporation mask according to (1), wherein a film thickness of the polymer film is smaller than a thickness of the substrate.

(3) The evaporation mask according to (1) or (2), wherein the film thickness of the polymer film is substantially equal to or less than 20 μm.

(4) The evaporation mask according to any one of (1) to (3), wherein an opening shape of the second opening section includes a minute shape according to the film thickness of the polymer film.

(5) The evaporation mask according to any one of (1) to (4), wherein
a plurality of the second opening sections are provided,
each opening shape of the plurality of the second opening sections includes a linear shape, and
the plurality of the second opening sections are provided side by side in a direction substantially perpendicular to an extending direction thereof.

(6) The evaporation mask according to any one of (1) to (5), wherein
a plurality of the second opening sections are provided, and
each opening shape of the plurality of the second opening sections includes a comb-like shape in part or all thereof.

(7) The evaporation mask according to any one of (1) to (6), wherein a photosensitive resin layer is provided on the polymer film.

(8) The evaporation mask according to any one of (1) to (7), wherein a photosensitive resin layer is provided on a second main surface side of the substrate.

(9) The evaporation mask according to any one of (1) to (8), wherein
a plurality of the first opening sections and a plurality of the second opening sections are provided, and
the first opening section and the second opening section are arranged in a fashion of one-to-one correspondence.

(10) The evaporation mask according to any one of (1) to (9), wherein
a plurality of the second opening sections are provided, and
two or more second opening sections are arranged oppositely to one first opening section.

(11) The evaporation mask according to any one of (1) to (10), wherein a width of a cross-sectional shape of the first opening section is larger on the first main surface side of the substrate than on the second main surface side of the substrate.

(12) An electronic device including:
a conductive film in a selective region on a substrate,
wherein in the conductive film, a foot section thereof is tilted with a slope being more moderate as its position is closer to the substrate side.

(13) The electronic device according to (12), wherein the conductive film is a source electrode and a drain electrode of a transistor.

(14) The electronic device according to (13) sequentially including from the substrate side:
a gate electrode;
a gate insulating film;
a semiconductor layer; and
a protective film,
wherein as the conductive film, the source electrode and the drain electrode are provided on the protective film, and
widths of part or all of the source electrode and the drain electrode are substantially equal to or less than 20 μm.

(15) The electronic device according to (13) or (14), wherein the source electrode and the drain electrode respectively include a comb-like shape.

(16) The electronic device according to any one of (12) to (15), the electronic device is an organic thin film transistor.

(17) A method of manufacturing an evaporation mask, the method including:
forming one or a plurality of first opening sections in a substrate; and
forming a polymer film including one or a plurality of second opening sections on a first main surface side of the substrate, the one or the plurality of second opening sections being communicated with the one or the plurality of first opening sections.

(18) The method according to (17), wherein
after the polymer film is formed on the first main surface side of the substrate and then a photosensitive resin layer is pattern-formed on the polymer film, the second opening section is formed in the polymer film by etching with use of the photosensitive resin layer as a mask, and
after another photosensitive resin layer is pattern-formed on a second main surface side of the substrate, the first opening section is formed in the substrate by etching with use of said another photosensitive resin layer as a mask.

(19) The method according to (17) or (18), wherein
after the polymer film is formed on the first main surface side of the substrate and subsequently a photosensitive resin layer is pattern-formed on the polymer film, the second opening section is formed in the polymer film by etching with use of the photosensitive resin layer as a mask, and
the first opening section is then formed in the substrate by etching with use of the polymer film including the second opening section as a mask.

(20) A method of manufacturing an electronic device, the method including
forming a conductive film by using an evaporation mask,
wherein the evaporation mask includes a substrate and a polymer film, the substrate including one or a plurality of first opening sections, and the polymer film being provided on a first main surface side of the substrate and including one or a plurality of second opening sections communicated with the respective first opening sections.

The present disclosure contains subject matter related to that disclosed in Japanese Priority Patent Application JP 2011-153872 filed in the Japanese Patent Office on Jul. 12, 2011, the entire contents of which is hereby incorporated by reference.

It should be understood by those skilled in the art that various modifications, combinations, sub-combinations, and alternations may occur depending on design requirements and other factors insofar as they are within the scope of the appended claims or the equivalents thereof.

What is claimed is:

1. An evaporation mask comprising:
a substrate including one or a plurality of first opening sections; and
a polymer film provided on a first main surface side of the substrate, the polymer film including one or a plurality of second opening sections communicated with the respective first opening sections.

2. The evaporation mask according to claim 1, wherein a film thickness of the polymer film is smaller than a thickness of the substrate.

3. The evaporation mask according to claim 2, wherein the film thickness of the polymer film is substantially equal to or less than 20 μm.

4. The evaporation mask according to claim 3, wherein an opening shape of the second opening section includes a minute shape according to the film thickness of the polymer film.

5. The evaporation mask according to claim 4, wherein
a plurality of the second opening sections are provided,
each opening shape of the plurality of the second opening sections includes a linear shape, and
the plurality of the second opening sections are provided side by side in a direction substantially perpendicular to an extending direction thereof.

6. The evaporation mask according to claim 4, wherein
a plurality of the second opening sections are provided, and
each opening shape of the plurality of the second opening sections includes a comb-like shape in part or all thereof.

7. The evaporation mask according to claim 1, wherein a photosensitive resin layer is provided on the polymer film.

8. The evaporation mask according to claim 1, wherein a photosensitive resin layer is provided on a second main surface side of the substrate.

9. The evaporation mask according to claim 1, wherein
a plurality of the first opening sections and a plurality of the second opening sections are provided, and
the first opening section and the second opening section are arranged in a fashion of one-to-one correspondence.

10. The evaporation mask according to claim 1, wherein
a plurality of the second opening sections are provided, and
two or more second opening sections are arranged oppositely to one first opening section.

11. The evaporation mask according to claim 1, wherein a width of a cross-sectional shape of the first opening section is larger on the first main surface side of the substrate than on the second main surface side of the substrate.

12. An electronic device comprising:
a conductive film in a selective region on a substrate,
wherein in the conductive film, a foot section thereof is tilted with a slope being more moderate as its position is closer to the substrate side.

13. The electronic device according to claim 12, wherein the conductive film is a source electrode and a drain electrode of a transistor.

14. The electronic device according to claim 13 sequentially comprising from the substrate side:
a gate electrode;
a gate insulating film;
a semiconductor layer; and
a protective film,
wherein as the conductive film, the source electrode and the drain electrode are provided on the protective film, and
widths of part or all of the source electrode and the drain electrode are substantially equal to or less than 20 μm.

15. The electronic device according to claim 14, wherein the source electrode and the drain electrode respectively include a comb-like shape.

16. The electronic device according to claim 12, the electronic device is an organic thin film transistor.

17. A method of manufacturing an evaporation mask, comprising:
forming one or a plurality of first opening sections in a substrate; and
forming a polymer film including one or a plurality of second opening sections on a first main surface side of the substrate, the one or the plurality of second opening sections being communicated with the one or the plurality of first opening sections.

18. The method according to claim 17, wherein
after the polymer film is formed on the first main surface side of the substrate and then a photosensitive resin layer is pattern-formed on the polymer film, the second opening section is formed in the polymer film by etching with use of the photosensitive resin layer as a mask, and
after another photosensitive resin layer is pattern-formed on a second main surface side of the substrate, the first opening section is formed in the substrate by etching with use of said another photosensitive resin layer as a mask.

19. The method according to claim 17, wherein
after the polymer film is formed on the first main surface side of the substrate and subsequently a photosensitive resin layer is pattern-formed on the polymer film, the second opening section is formed in the polymer film by etching with use of the photosensitive resin layer as a mask, and
the first opening section is then formed in the substrate by etching with use of the polymer film including the second opening section as a mask.

20. A method of manufacturing an electronic device, the method comprising
forming a conductive film by using an evaporation mask,
wherein the evaporation mask includes a substrate and a polymer film, the substrate including one or a plurality of first opening sections, and the polymer film being provided on a first main surface side of the substrate and including one or a plurality of second opening sections communicated with the respective first opening sections.
